(19) United States
(12) Patent Application Publication
(10) Pub. No.: US 2025/0107601 A1
(43) Pub. Date: Apr. 3, 2025

(54) Accessorized Laptop Shell Case

(71) Applicant: Ali Mirzabeili, Bucharest (RO)

(72) Inventor: Ali Mirzabeili, Bucharest (RO)

(21) Appl. No.: 18/477,182

(22) Filed: Sep. 28, 2023

(51) Int. Cl. A45C 11/00; A45C 15/06; H01L 25/075

(52) U.S. Cl. CPC A45C 11/00; A45C 15/06; H01L 25/0753; A45C 11/003

(57) ABSTRACT

An accessorized laptop shell case is an apparatus that enables users to increase the functionality of a laptop by accommodating different laptop accessories without impacting the portability of the laptop. The apparatus includes comprises a lid shell, a powering data connector, a display screen, and a plurality of accessory connectors. The lid shell serves as the base where various laptop accessories can be attached to. The lid shell also secures the laptop accessories to the laptop's lid to maintain an overall portable structure. The powering data connector enables the electrical connection and electronic connection between the laptop accessories and the laptop's system. The display screen enables users to output media from the apparatus. The plurality of accessory connectors secures the display screen and the laptop accessories to the lid shell. The plurality of accessory connectors enables the transmission of data and power between the laptop's system and the laptop accessories.

### FIELD OF THE INVENTION

The present invention relates generally to computer accessories. More specifically, the present invention provides a laptop case with user-friendly means to facilitate the customization of the laptop case to extend the functionality of the laptop equipped with the laptop case.

### BACKGROUND OF THE INVENTION

Nowadays, several laptop accessories are available to help protect the laptop or to increase the functionality of the laptop. For example, laptop covers are available that protect the exterior of the laptop. However, most of the available laptop cases have limited functionality. For example, most laptop cases are either cloth-based, zippered pouches, or plastic-based covers that clip on to the laptop lid and base. Neither provide additional functional features to the laptop aside from physical protection and a degree of artistic expression. Some laptop cases have been made available to expand the laptop's native capabilities through extension cables with integrated ports and with compartments that house external batteries and data storage units. However, these laptop cases only provide a limited degree of functionality in that certain external devices cannot be hosted by the limited array of available ports and connectors. Therefore, there is a need for a laptop case that can compactly house various laptop accessories for increased functionality, facile transport, space economy, and aesthetic value.

An objective of the present invention is to provide an accessorized laptop shell case that can extend the functionality of the laptop in a user-friendly, highly flexible, and portable manner. The present invention is a case that can be fitted onto any portable computer and houses a variety of integrated ports which can host different electronic and electrical components and devices depending on user preference. Another objective of the present invention is to provide accessorized laptop shell case that includes various integrated accessories that increase the functionality of the laptop. The present invention can include integrated means for projecting light and media, physical means for the user to control different applications on the laptop and external devices, as well as means to accommodate different laptop accessories. Additional features and benefits of the present invention are further discussed in the sections below.

### SUMMARY OF THE INVENTION

The present invention is an accessorized laptop shell case. The present invention enables users to increase the functionality of the laptop equipped with the present invention. To do so, the present invention includes shell case structure with several integrated accessory connectors that enable compatible laptop accessories to be mounted onto the accessorized laptop shell case. The present invention can include, but is not limited to, built-in Printed Circuit Boards (PCBs) with Integrated Circuit (IC) chips that accommodate the different accessory connectors to receive the different accessories. The accessory connectors can include, but are not limited to, PCI, SATA, mSATA, M.2, NGFF, NF-1, U.2, U.3, USB, USB-C, HDMI, DisplayPort, RJ45, FireWire, Optical, Coaxial, Memory Card, etc. In addition, the accessories can include, but are not limited to, PCI-card(s), SSD disk(s). memory card(s), display(s), camera(s), battery(s), network router(s), power adapter(s), etc. Further, any of the laptop accessories can be selectively attached to the present invention in the arrangement the user desires. This way, the present invention allows the user to customize the additional functionalities provided by the present invention with the selected laptop accessories attached.

### BRIEF DESCRIPTION OF THE DRAWINGS

FIG. 1 is a top-front-exploded perspective view of the present invention, wherein the lid shell is shown being attached to a laptop's lid.

FIG. 2 is a top-front perspective view of the present invention, wherein the lid shell is shown attached to a laptop's lid.

FIG. 3 is a top-rear perspective view of the present invention, wherein the lid shell is shown being attached to a laptop's lid.

FIG. 4 is a top-front perspective view of the present invention, wherein the lid shell is shown with a plurality of board-to-board connectors and a plurality of Light Emitting Diodes (LEDs).

FIG. 5 is a front view of the present invention, wherein the lid shell is shown with the plurality of board-to-board connectors and the plurality of LEDs.

FIG. 6 is a top-front perspective view of the present invention, wherein the lid shell is shown with a plurality of pin connectors.

FIG. 7 is a front view of the present invention, wherein the lid shell is shown with the plurality of pin connectors.

FIG. 8 is a top-front perspective view of the present invention, wherein the lid shell is shown with a plurality of magnetic connectors.

FIG. 9 is a front view of the present invention, wherein the lid shell is shown with the plurality of magnetic connectors.

FIG. 10 is a top-front perspective view of the present invention, wherein the present invention is shown with laptop accessories attached to the lid shell.

FIG. 11 is a front view of the present invention, wherein the present invention is shown with laptop accessories attached to the lid shell.

FIG. 12 is a top-front-exploded perspective view of the present invention.

FIG. 13 is a top-rear-exploded perspective view of the present invention.

FIG. 14 is a top-front perspective view of the present invention, wherein at least one deployable light and at least one media capture device are shown deployed.

FIG. 15 is a front view of the present invention, wherein the at least one deployable light and the at least one media capture device are shown deployed.

FIG. 16 is a rear view of the present invention, wherein the at least one deployable light and the at least one media capture device are shown deployed.

FIG. 17 is a top-front-exploded perspective view of the present invention, wherein at least one compartment lid is shown removed from at least one compartment receptacle of at least one accessory compartment.

FIG. 18 is a top-front perspective view of the present invention, wherein the present invention is shown with at least one accessory holder and at least one data port mounted onto the lid shell.

FIG. 19 is a front view of the present invention, wherein the present invention is shown with the at least one accessory holder and the at least one data port mounted onto the lid shell.

FIG. 20 is a top-front perspective view of an alternate embodiment of the lid shell of the present invention.

FIG. 21 is a top-front view of the alternate embodiment of the lid shell of the present invention.

FIG. 22 is a schematic view showing the electrical connections and the electronic connections of the present invention, wherein the electrical connections are shown in solid lines, and the electronic connections are shown in dashed lines.

### DETAILED DESCRIPTION OF THE INVENTION

All illustrations of the drawings are for the purpose of describing selected versions of the present invention and are not intended to limit the scope of the present invention.

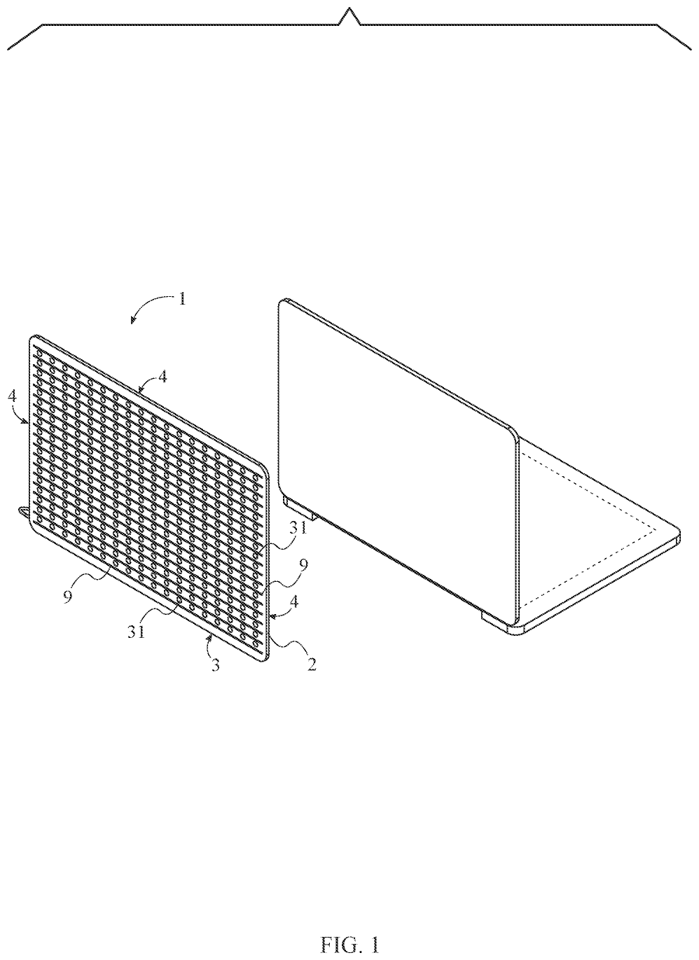

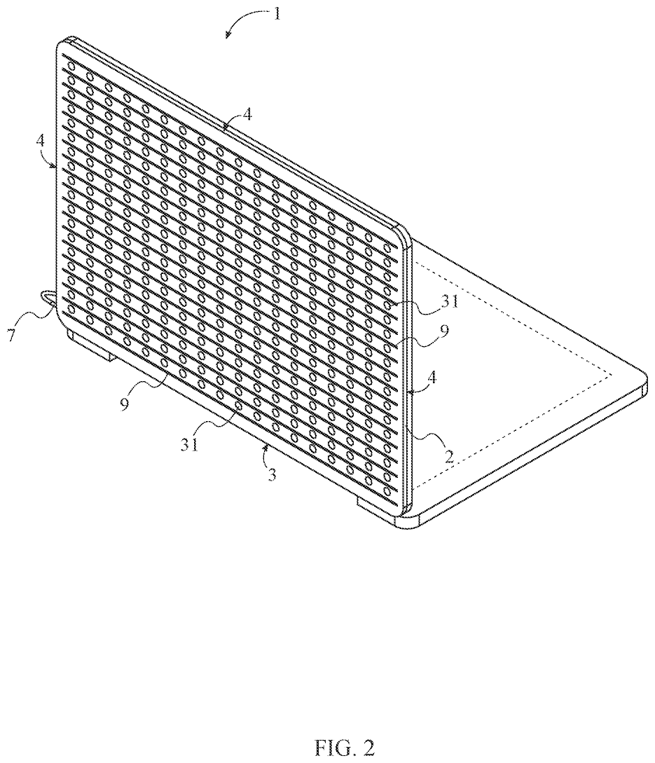

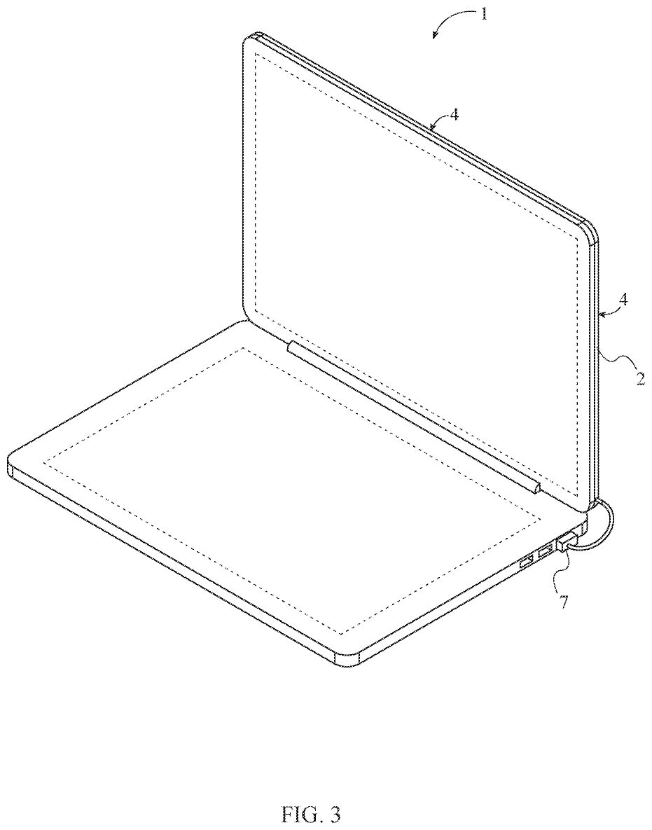

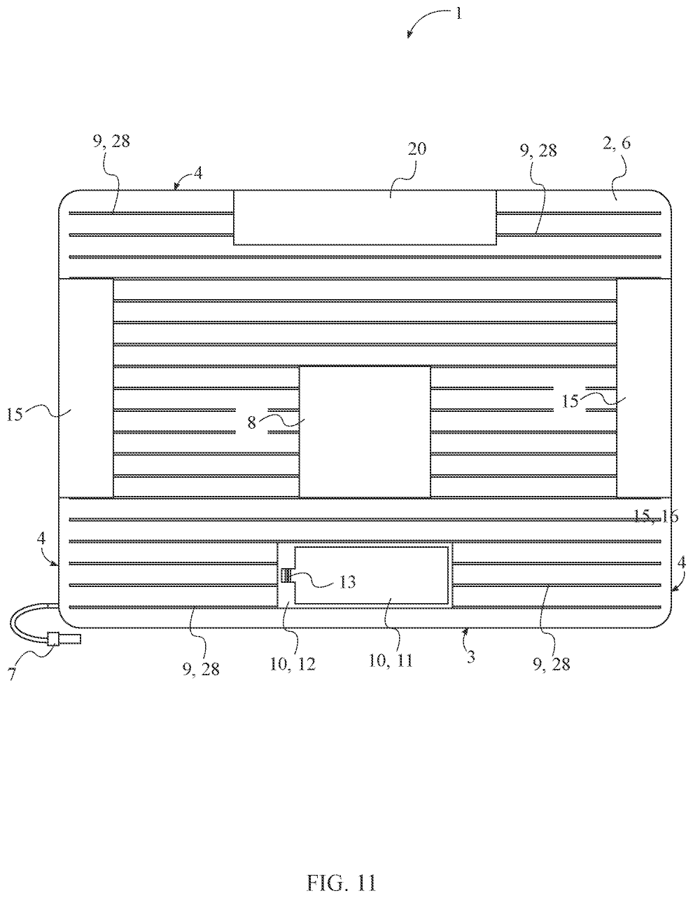

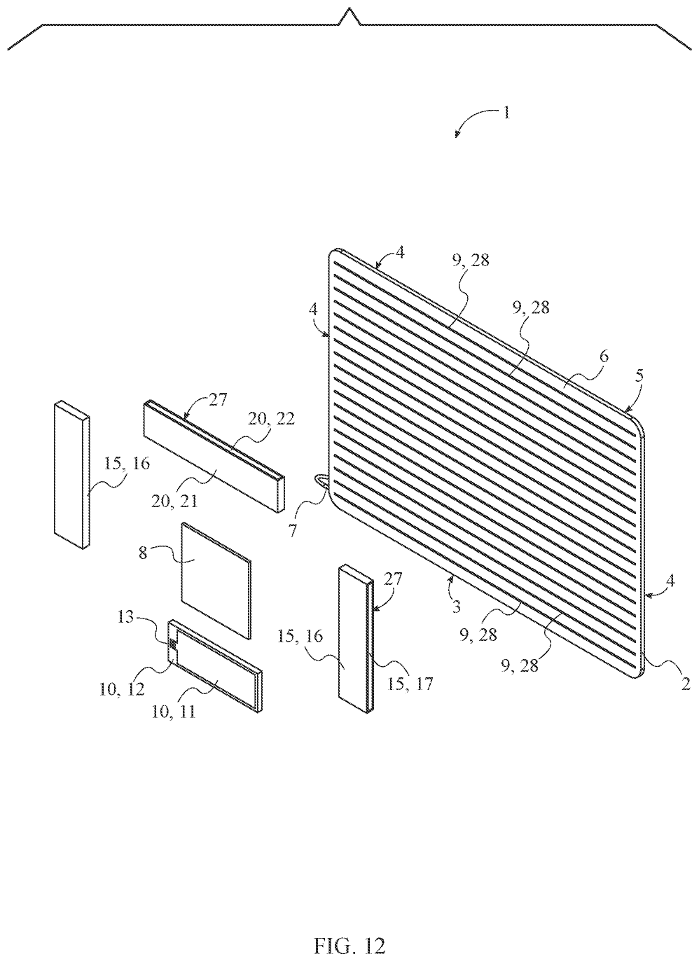

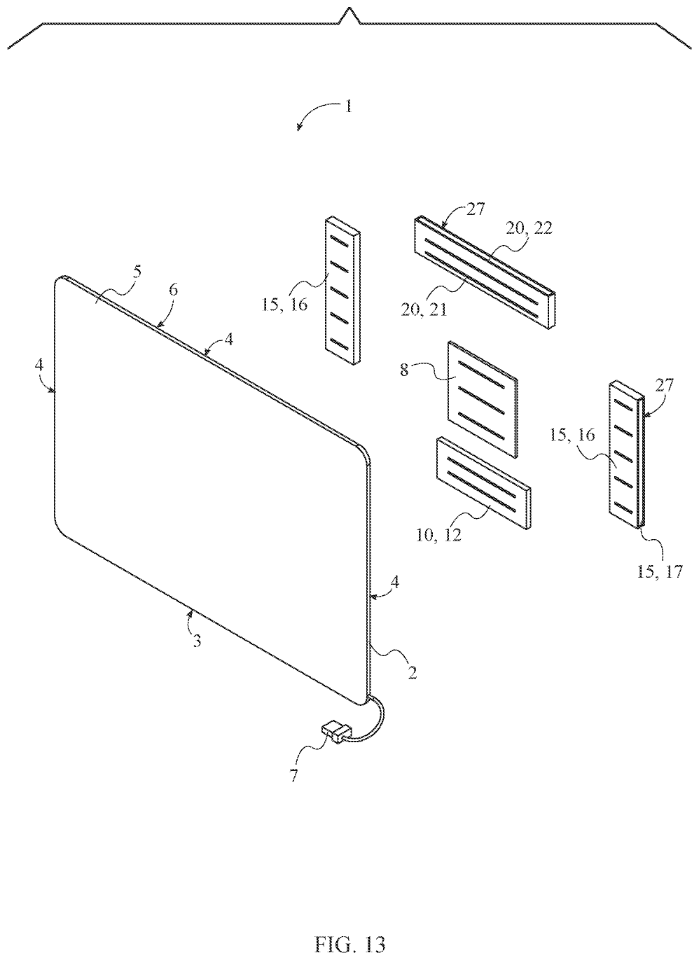

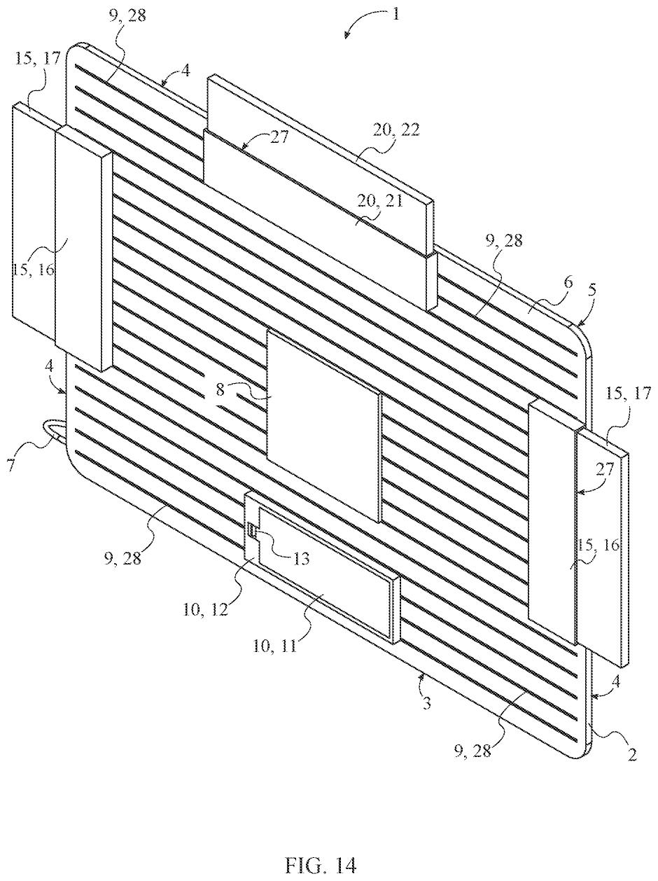

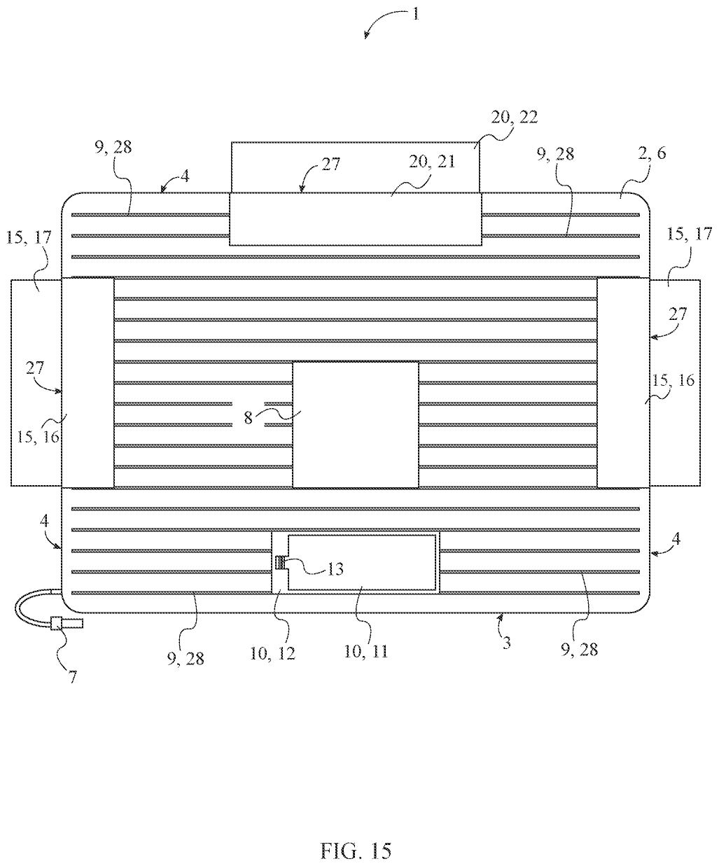

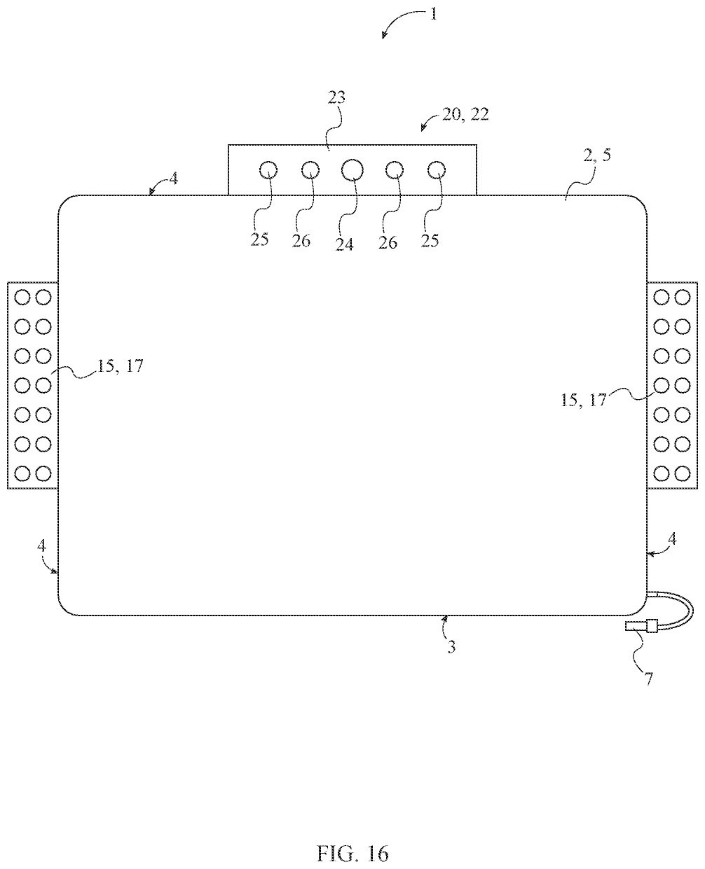

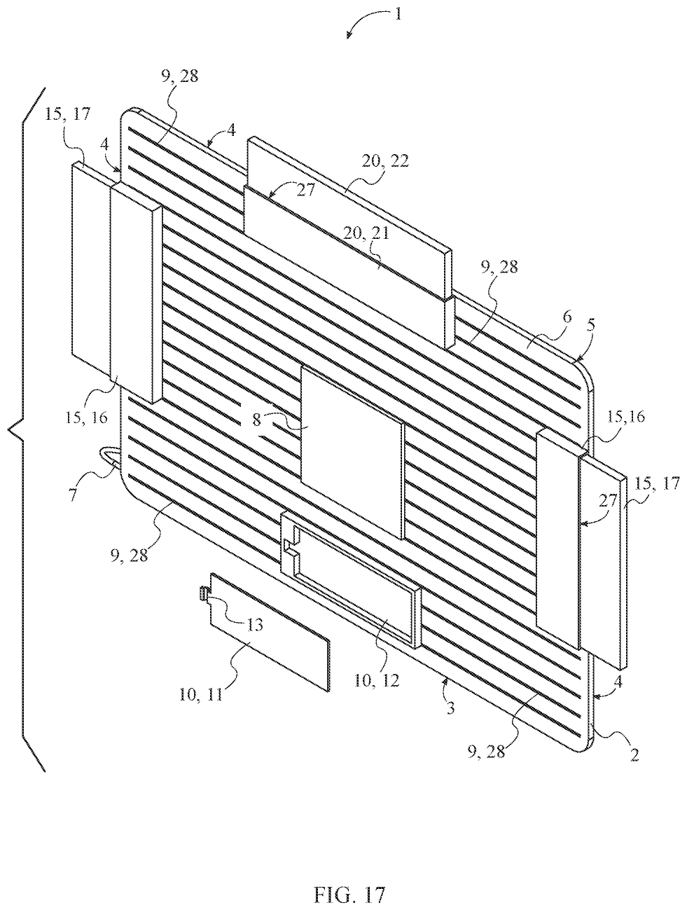

The present invention is an accessorized laptop shell case that enables users to increase the functionality of a laptop by accommodating different laptop accessories without impacting the portability of the laptop. As can be seen in FIGS. 1 through 3 and 10 through 19, the present invention comprises a lid shell 1, a powering data connector 7, a display screen 8, and a plurality of accessory connectors 9. The lid shell 1 serves as the mounting base where various laptop accessories can be attached to. The lid shell 1 also secures the attached laptop accessories to the laptop's lid to maintain an overall portable structure. The powering data connector 7 enables the electrical connection and electronic connection between the attached laptop accessories and the laptop's system. The display screen 8 enables users to output different media behind the laptop's screen. The plurality of accessory connectors 9 enables the user to secure the display screen 8 and the attached laptop accessories to the lid shell 1. The plurality of accessory connectors 9 also enables the transmission of data and power between the laptop system and the attached laptop accessories.

The general configuration of the aforementioned components enables users to increase the laptop's functionality without limiting the transportability of the laptop or hindering the user's comfort. As can be seen in FIGS. 1 through 3, 10 through 19, and 22, the lid shell 1 is preferably designed to cover the back of the laptop's lid in order to accommodate several laptop accessories that increase the functionality of the laptop. To do so, the lid shell 1 comprises a shell body 2, a proximal shell face 5, and a distal shell face 6. The shell body 2 is preferably a planar thin structure with a size and shape that matches the size and shape of the laptop's lid. The proximal shell face 5 and the distal shell face 6 correspond to the opposite flat surfaces of the shell body 2. Accordingly, the proximal shell face 5 and the distal shell face 6 are positioned opposite to each other about the lid shell 1. The proximal shell face 5 preferably corresponds to the surface of the shell body 2 that is mounted onto the rear of the laptop's lid. Various mounting mechanisms can be implemented on the proximal shell face 5 to enable the attachment of the shell body 2 to the laptop's lid. Further, the distal shell face 6 corresponds to the surface of the shell body 2 that accommodates the plurality of accessory connectors 9. Further, the powering data connector 7 is peripherally mounted to the shell body 2 so that the powering data connector 7 can be plugged into a corresponding laptop's port. For example, the powering data connector 7 can be a Universal Serial Bus (USB) connector that can be plugged into a USB port on the laptop.

Further, as can be seen in FIGS. 1 through 3, 10 through 19, and 22, the plurality of accessory connectors 9 is distributed across the distal shell face 6 to accommodate several laptop accessories. The distribution of the plurality of accessory connectors 9 enables the user to attach the desired laptop accessories to different locations around the lid shell 1. In addition, the plurality of accessory connectors 9 is integrated into the shell body 2 so that the selected laptop accessories are securely attached to the lid shell 1 with the corresponding accessory connectors 9. Further, the plurality of accessory connectors 9 is electrically and electronically connected to the powering data connector 7 so that the appropriate data and power is transmitted between the laptop's system and the attached laptop accessories. Furthermore, the display screen 8 is electrically and electronically engaged into at least one corresponding accessory connector from the plurality of accessory connectors 9. This way, the display screen 8 can be used to display selected media including, but not limited to, graphics, letters, numbers, etc. For example, the display screen 8 can be a smaller digital screen including, but not limited to, an LCD screen, an OLED screen, an LED screen, or an electronic paper screen.

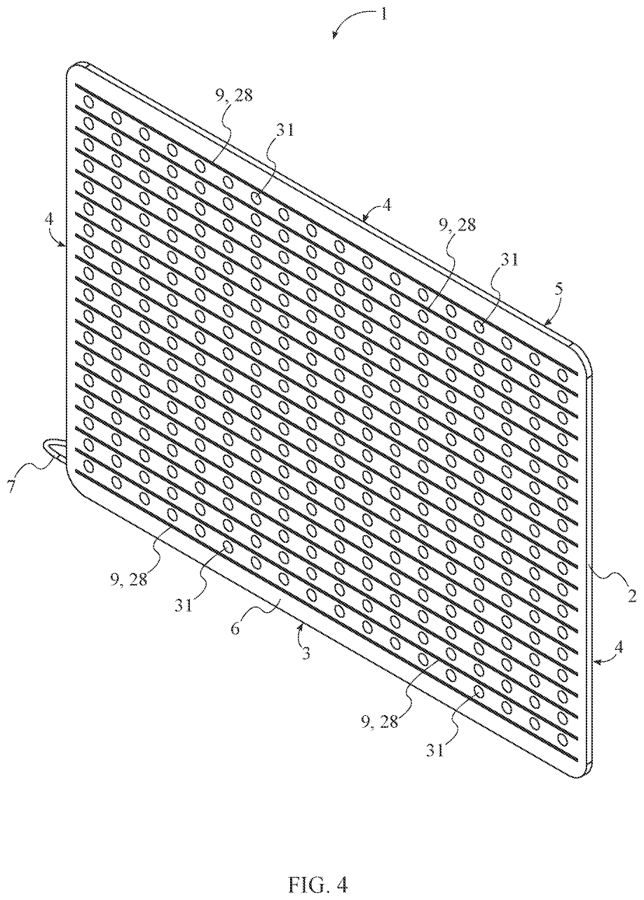

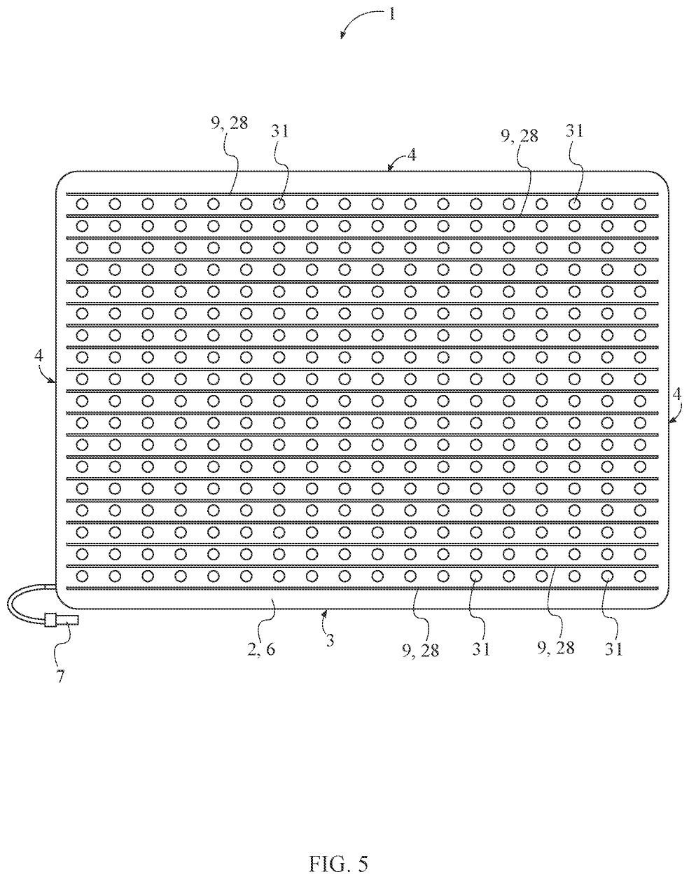

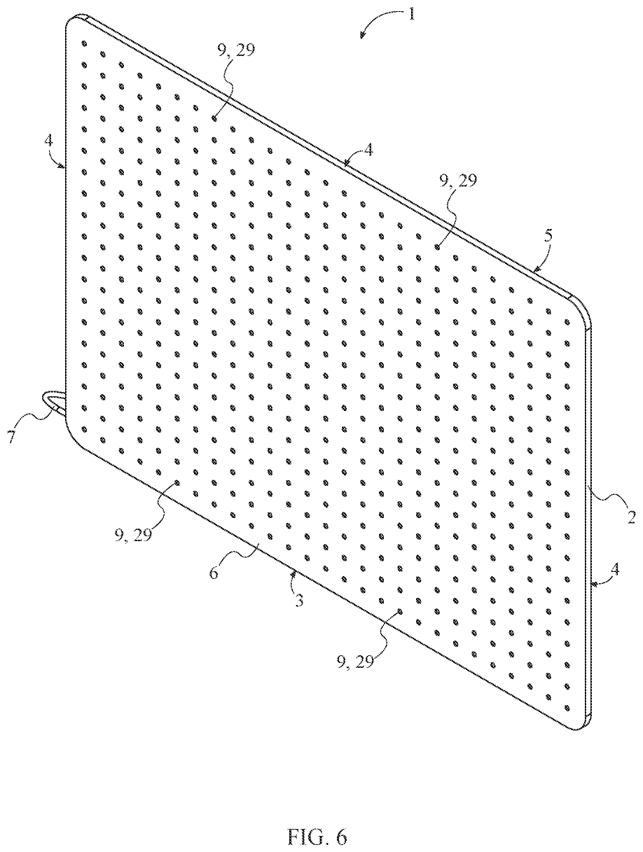

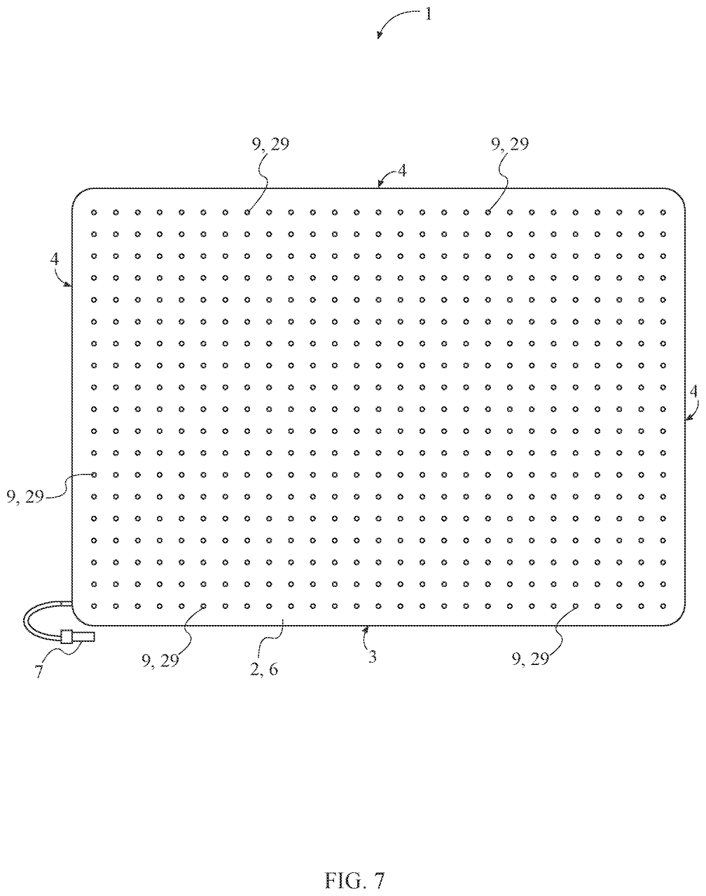

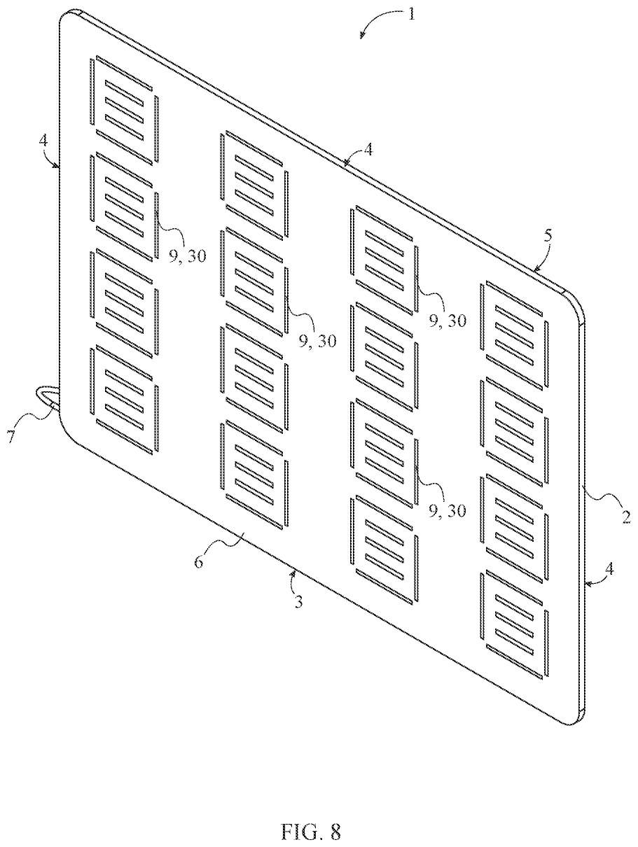

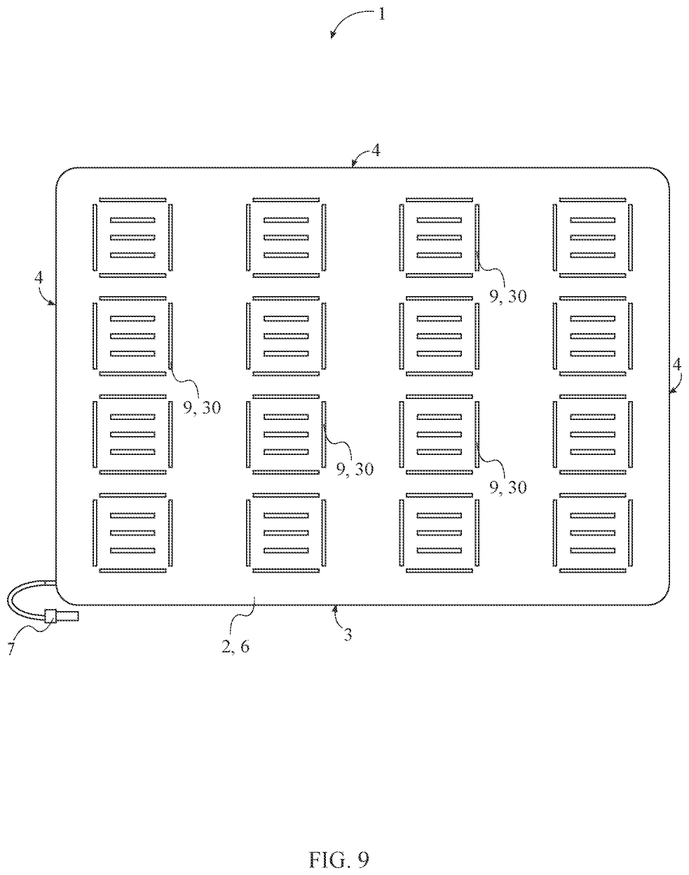

Furthermore, the plurality of accessory connectors 9 can include different types of connectors that accommodate different laptop accessories. As can be seen in FIGS. 4 through 9, the plurality of accessory connectors 9 can include, but is not limited to, a plurality of board-to-board connectors 28, a plurality of pin connectors 29, and/or a plurality of magnetic connectors 30. The plurality of board-to-board connectors 28, the plurality of pin connectors 29, and the plurality of magnetic connectors 30 enable the user to attach the desired laptop accessories to the shell body 2 without the use of additional mounting devices. The plurality of board-to-board connectors 28, the plurality of pin connectors 29, and the plurality of magnetic connectors 30 also enable the transmission of power and data between the attached laptop accessories and the laptop's system. In alternate embodiments, the display screen 8 can be replaced with analog display mechanisms to display ornamental media. Further, different accessory connectors that enable the electronic and the electrical connection of the laptop accessories to the lid shell 1 can be implemented.

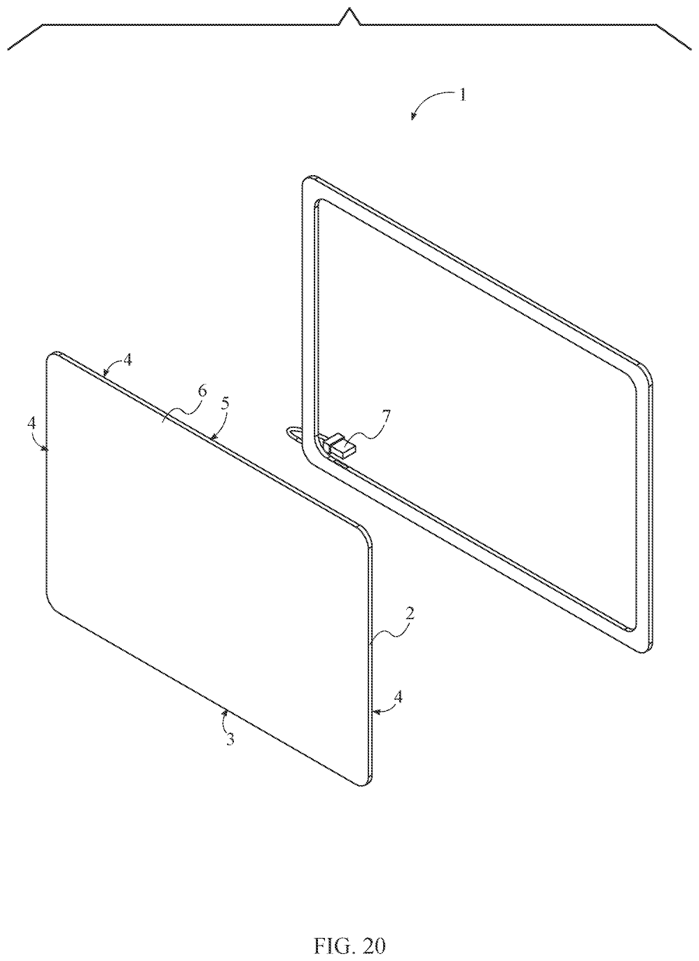

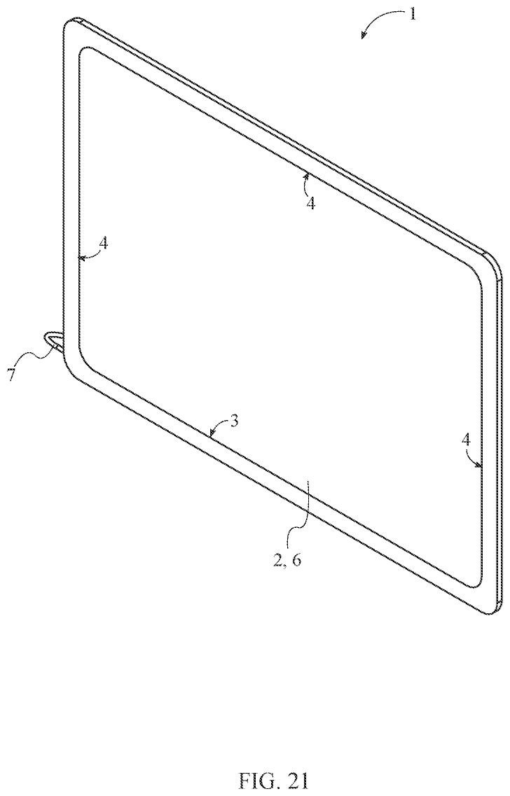

In some embodiments, the lid shell 1 can be provided as a modular structure that enables the partial removal of the some of the components of the lid shell 1. In this embodiment, the lid shell 1 may further comprise a body frame. As can be seen in FIGS. 20 and 21, the body frame corresponds to a separate portion of the lid shell 1 that surrounds the shell body 2. The body frame enables the quick attachment and removal of the shell body 2. To do so, the body frame comprises an outer perimeter, an inner perimeter, and a body connector. The outer perimeter of the body frame matches the outer perimeter of the laptop's lid, while the inner perimeter of the body frame matches the outer perimeter of the shell body 2. The body connector enables the attachment of the shell body 2 to the body frame. However, in this embodiment, the powering data connector 7 is peripherally mounted to the body frame instead of the shell body 2. Instead, the body connector serves to connect the shell body 2 electrically and electronically to the powering data connector 7 so that the selected laptop accessories attached to the shell body 2 can be connected to the laptop via the powering data connector 7. Thus, the body frame can be left attached to the laptop's lid while enabling the shell body 2 to be replaced if needed. In other embodiments, the shell lid can be provided as a smaller structure that can be attached to portions of the laptop's lid without covering the entirety of the laptop's lid.

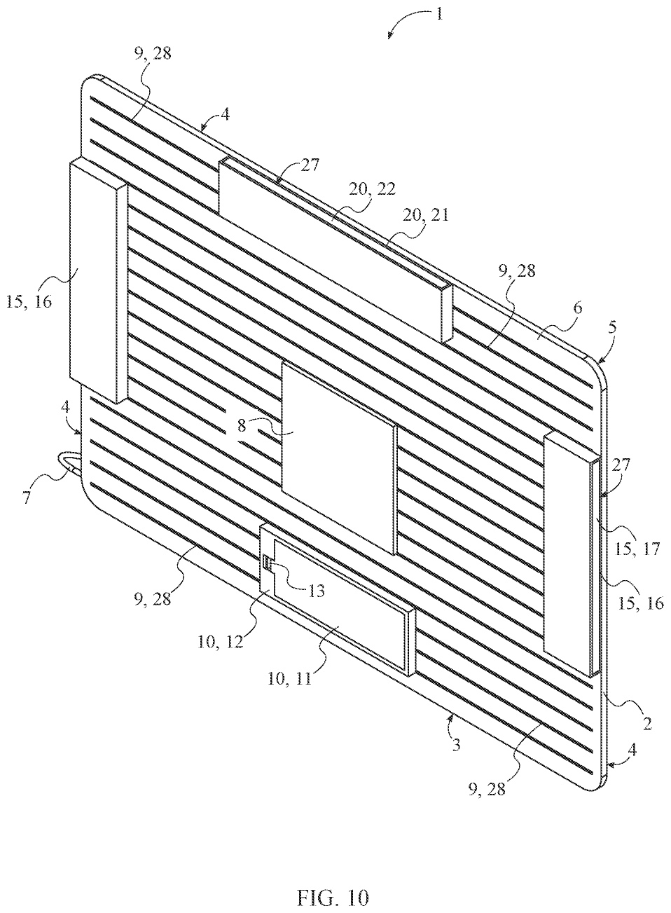

As previously discussed, the present invention enables the attachment of various laptop accessories to the lid shell 1 to serve as peripheral devices for the laptop. However, some laptop accessories may require special mounting structures, such as Printed Circuit Boards (PCBs). As can be seen in FIGS. 10 through 17, to accommodate these laptop accessories, the present invention may further comprise at least one accessory compartment 10 that enables the secure attachment of the laptop accessory to the shell body 2. The laptop accessories that can be attached to the shell body 2 using the at least one accessory compartment 10 can include, but are not limited to, PCI-cards, SSD disks, memory cards, batteries, network routers, power adapters, etc. In addition, the present invention may further comprise at least one accessory holder 14 that enables the mounting of larger laptop accessories to the shell body 2. For example, the accessory holder can retain additional cables, such as USB cables, for later use. The at least one accessory holder 14 can be designed to retain cables such as flex-rigid cable(s) that can be used to extend the length of the original camera cable. So, the at least one accessory compartment 10 and the at least one accessory holder 14 are peripherally mounted to the shell body 2. This way, additional laptop accessories can be attached to the shell body 2 without obstruction from the at least one accessory compartment 10 or the at least one accessory holder 14. In addition, the at least one accessory compartment 10 and the at least one accessory holder 14 are mounted onto the distal shell face 6 to securely retain the selected laptop accessories. In other embodiments, different mounting devices can be utilized to secure different laptop accessories to the shell body 2.

The at least one accessory compartment 10 can be positioned on several locations throughout the distal shell face 6 and several accessory compartments 10 can be attached to the shell body 2. For example, as can be seen in FIGS. 10 through 17, the shell body 2 may comprise a fixed peripheral edge 3 that corresponds to the edge adjacent to the laptop's base. The at least one accessory compartment 10 may then be centrally positioned along the fixed peripheral edge 3 to leave space for the other laptop accessories throughout the shell body 2. Further, several accessory compartments 10 can be provided throughout the shell body 2 to accommodate several laptop accessories that require additional mounting support. In addition, to securely retain the selected laptop accessories, the at least one accessory compartment 10 can be designed to enclose the selected laptop accessories when mounted onto the shell body 2 using the corresponding accessory compartment. To do so, the at least one accessory compartment 10 may comprise at least one compartment lid 11, at least one compartment receptacle 12, and at least one snap connector 13. The at least one compartment receptacle 12 is designed to receive the selected laptop accessory, while the at least one compartment lid 11 seals the at least one compartment receptacle 12 to protect the retained laptop accessory. The at least one snap connector 13 facilitates the attachment of the at least one compartment lid 11 to the at least one compartment receptacle 12. So, the at least one compartment receptacle 12 is integrated into the distal shell face 6 to receive the selected laptop accessory. Further, the at least one compartment lid 11 is attached onto the at least one compartment receptacle 12 by the at least one snap connector 13 to secure the at least one compartment lid 11 to the at least one compartment receptacle 12. In other embodiments, the at least one accessory compartment 10 can be modified to retain different laptop accessories.

In some embodiments, the some of the laptop accessories the present invention can accommodate include lighting accessories. Some lighting accessories can be used as additional lighting that illuminates the user during a video recording for better image quality. As can be seen in FIGS. 10 through 17, the present invention may further comprise at least one deployable light 15 that can be selectively deployed to illuminate the user. Thus, the at least one deployable light 15 is peripherally positioned to the shell body 2 so that the at least one deployable light 15 can be deployed outwards, away from the shell body 2. Further, the at least one deployable light 15 is electrically and electronically engaged into at least one corresponding accessory connector from the plurality of accessory connectors 9 so that the operation of the at least one deployable light 15 can be controlled from the laptop's User Interface (UI). Alternatively, the at least one deployable light 15 can be adapted to be remotely controlled using a corresponding remote control or through a software application installed on a Personal Computing (PC) device including, but not limited to, a mobile application. Further, the at least one deployable light 15 can also be configured to emit light towards the surroundings of the laptop for ornamental or other functional functions.

The at least deployable light can be arranged to broadly illuminate the user during a video recording or other similar media capture. As can be seen in FIGS. 10 through 17, the at least one deployable light 15 may comprise at least one light housing 16 and at least one light source 17. The at least one light housing 16 corresponds to the structure that retains the at least one light source 17 when not in use. The at least one light source 17 can be any type of light source that emits a light in the desired wavelength. To optimize the location of the at least one deployable light 15, the at least one light housing 16 is centrally positioned along an at least one free peripheral edge 4. The at least one free peripheral edge 4 corresponds to an edge of the shell body 2 that is not adjacent to the edge of the laptop's lid that is connected to the laptop's base. In addition, the at least one light housing 16 is mounted onto the distal shell face 6 to securely the at least one light housing 16 to the shell body 2. Further, an elongated opening 27 of the at least one light housing 16 is oriented towards the at least one free peripheral edge 4 so that when the at least one light source 17 is deployed, the at least one light source 17 is not blocked by the shell body 2. Furthermore, the at least one light source 17 is slidably mounted into the at least one light housing 16 so that the at least one light source 17 can be deployed as desired by the user. In some embodiments, several deployable lights 15 can be provided along the free peripheral edges 4 of the shell body 2. This way, the several deployable lights 15 can be arranged in an arrangement resembling a ring light to provide the best illumination to the user.

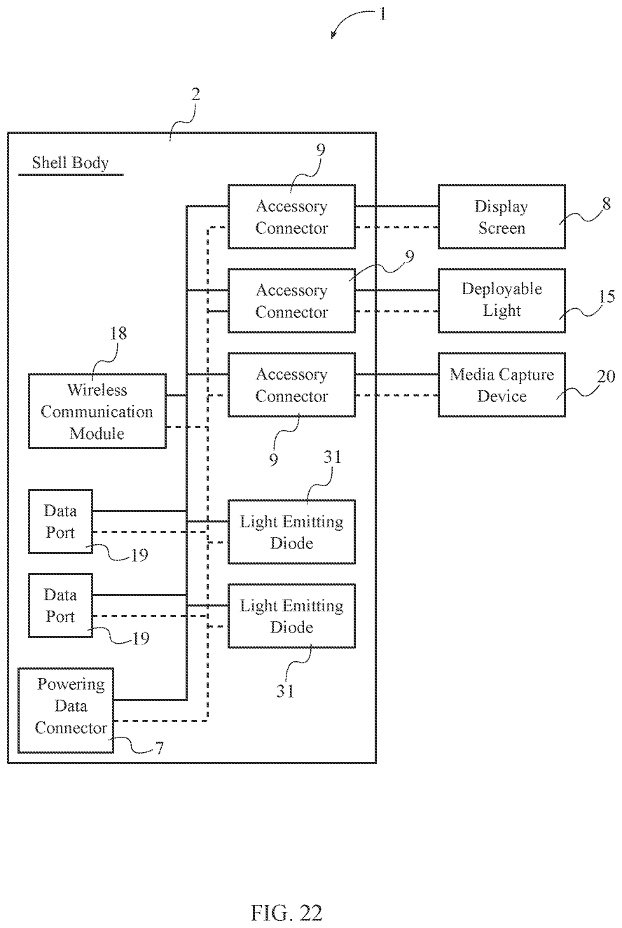

In some embodiments, the present invention can include means to enable the wireless communication between the laptop and other wireless devices. As can be seen in FIG. 22, the present invention may further comprise a wireless communication module 18 that enables the wireless communication between the laptop and other wireless devices. The wireless communication module 18 is mounted within the shell body 2 to protect the wireless communication module 18 from the surroundings. In addition, the wireless communication module 18 is electrically and electronically connected to the powering data connector 7 to enable the transmission of data signals between the laptop and the wireless communication module 18. This way, the wireless communication module 18 enables the data exchange with other external devices. For example, the wireless communication module 18 can implement Near Field Communication (NFC), Wi-Fi, Bluetooth, Ultra-Wide Band (UWB) radio technology, or any other similar short-range wireless technology that enables the wireless transmission between the laptop's system and the external object. Furthermore, the wireless communication module 18 can be configured to enable the remote control of the attached laptop accessories without direct input from the laptop. For example, an associated software application in the form of a mobile application for a smartphone can be provided to enable the user control from the smartphone one or more attached laptop accessories such as the display screen 8, integrated lights, etc. The software application can be provided in different forms that are compatible with different computing devices including, but not limited to, desktop applications, cloud applications, widgets, add-ons, etc.

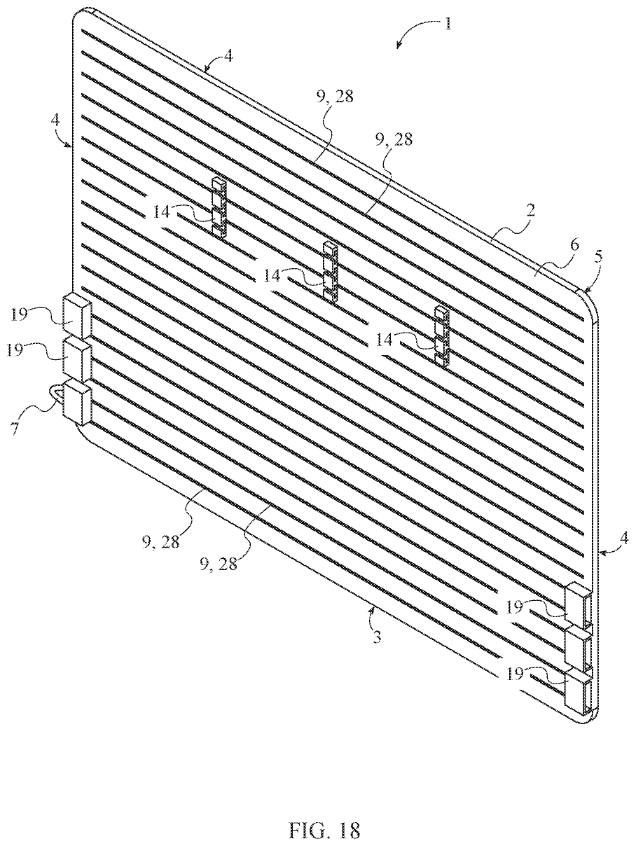

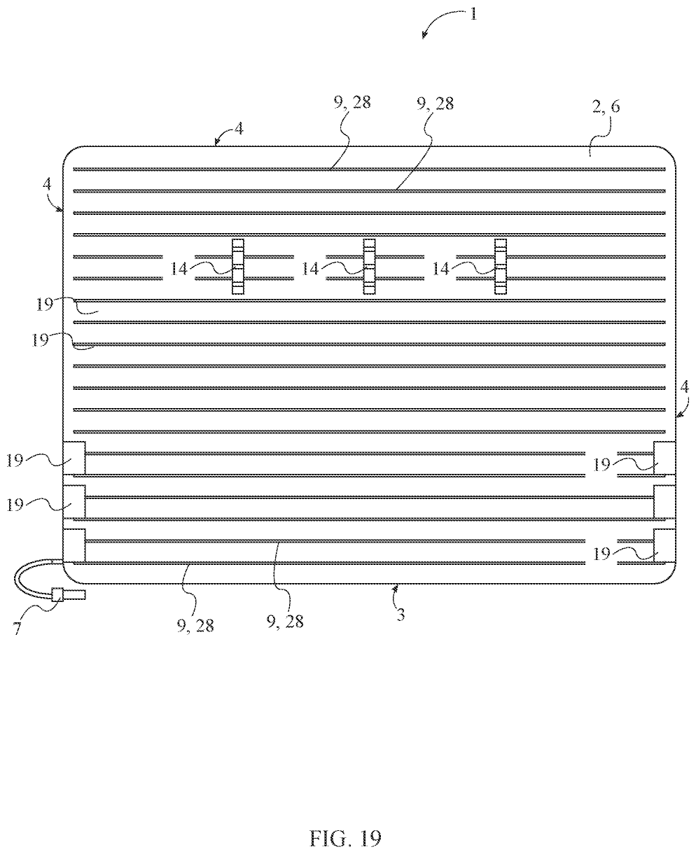

In other embodiments, the present invention can provide means for the user to connect other laptop accessories and peripherals via the present invention. As can be seen in FIGS. 18 and 19, the present invention may further comprise at least one data port 19. The at least one data port 19 enables the user to plug in other laptop accessories to the laptop without using the laptop's data ports. The at least one data port 19 is peripherally positioned to the shell body 2 to facilitate the connection of the selected laptop accessory to the at least one data port 19. In addition, the at least one data port 19 is electrically and electronically connected to the powering data connector 7 to enable the data and power transmission between the laptop and the at least one data port 19. Further, the at least one data port 19 can be provided in several types of ports that serve as an interface to transfer signals between the attached laptop accessories and the laptop's system. For example, the at least one data port 19 can include, but is not limited to, a PCI port, SATA port, M.2 port, NGFF port, NF-1 port, USB port, HDMI port, DisplayPort, RJ45 port, Coaxial port, or Memory Card port.

Further, several data ports 19 can be provided to accommodate several laptop accessories. As can be seen in FIGS. 18 and 19, the several data ports 19 can include the same type of ports or can include different types of ports distributed around the shell body 2. However, the data ports 19 are distributed in such a way that the laptop accessories connected to the data ports 19 do not obstruct the operation of the laptop or the user's comfort. For example, in one embodiment, the at least one data port 19 is oriented towards the at least one free peripheral edge 4 to enable the selected laptop accessory to be connected to the at least one data port 19 on the side of the shell body 2. In addition, the at least one data port 19 is positioned adjacent to the at least one fixed peripheral edge 3 to not add weight to the top of the laptop's lid. Further, several data ports 19 can be distributed along the at least one free peripheral edge 4 to accommodate additional peripherals. Additional data ports 19 can be provided on both lateral free peripheral edges 4 of the shell body 2 to accommodate a greater number of laptop accessories without unnecessarily piling up the number of laptop accessories on one side of the shell body 2. Further, specific data ports 19 can be provided to accommodate specific laptop accessories such as, but not limited to, media data ports 19 to accommodate a separate camera.

In addition to improving the lighting for the user, the present invention can further provide means for media capturing along with or without the use of the laptop's integrated media capturing device. As can be seen in FIGS. 10 through 17, the present invention may further comprise at least one media capture device 20 that provides an alternate means for media capture to the user. The at least one media capture device 20 is peripherally positioned to the shell body 2 so that the at least one media capture device 20 is not obstructed by the shell body 2. The at least one media capture device 20 is also electrically and electronically engaged into at least one corresponding accessory connector from the plurality of accessory connectors 9 to enable the transmission of data and power between the laptop and the at least one media capture device 20. In other embodiments, the at least one media capture device 20 can be provided as a removable device that can be repositioned to orient the media capture device as desired. For example, the at least one media capture device 20 can be a portable camera equipped with a flexible arm that allows the camera to be repositioned to the user's desired orientation. In addition, the flexible arm houses the wiring that connects the camera to an appropriate connector so that the camera can be plugged into an appropriate data port on the shell body 2 or directly to a laptop's data port. This way, the removable camera can be deployed as necessary if the user needs to capture media from different angles that the laptop's integrated camera cannot reach.

Similar to the at least one deployable light 15, the at least one media capture device 20 can be designed to be selectively deployed when the user needs to capture media. As can be seen in FIGS. 10 through 17, the at least one media capture device 20 may comprise at least one camera housing 21 and at least one camera assembly 22. The at least one camera housing 21 retains the at least one camera assembly 22 when not in use to protect the at least one camera assembly 22. The at least one camera assembly 22 is designed to capture various media including, but not limited to, photography, video, etc. The at least one camera housing 21 is centrally positioned along the at least one free peripheral edge 4 to position the at least one camera assembly 22 in an optimal position on the shell body 2 to capture media. For example, the at least one camera housing 21 can be positioned on the free peripheral edge 4 corresponding to the free peripheral edge 4 positioned opposite to the fixed peripheral edge 3. In addition, the at least one camera housing 21 is mounted onto the distal shell face 6 to secure the at least one camera housing 21 to the shell body 2. Further, an elongated opening 27 of the at least one camera housing 21 is oriented towards the at least one free peripheral edge 4 so that the at least one camera assembly 22 is not obstructed by the shell body 2 when deployed. Furthermore, the at least one camera assembly 22 is slidably mounted into the at least one camera housing 21 so that the at least one camera assembly 22 can be selectively deployed when needed. In other embodiments, different media capturing devices can be implemented.

In addition to the media capturing means of the at least one media capture device 20, the at least one media capture device 20 can include means to enhance the media capturing of different media. As can be seen in FIGS. 10 through 17, the at least one media capturing device 20 may further comprise an elongated assembly body 23, at least one imager 24, at least one flash source 25, and at least one camera sensor 26. The elongated assembly body 23 corresponds to the structure that securely retains the at least one imager 24, the at least one flash source 25, and the at least one camera sensor 26. The at least one imager 24 corresponds to the mechanism that enables the media capturing. The at least one flash source 25 generates additional lighting to enhance the media capturing, while the at least one camera sensor 26 improves the media capturing of the at least one imager 24. Accordingly, the elongated assembly body 23 is slidably mounted into the at least one camera housing 21 to enable the selective deployment of the at least one imager 24, the at least one flash source 25, and the at least one camera sensor 26. Further, the at least one imager 24, the at least one flash source 25, and the at least one camera sensor 26 are integrated along the elongated assembly body 23 to secure the at least one imager 24, the at least one flash source 25, and the at least one camera sensor 26 to the elongated assembly body 23. Furthermore, the at least one imager 24, the at least one flash source 25, and the at least one camera sensor 26 are oriented towards the proximal shell face 5 so that the at least one imager 24, the at least one flash source 25, and the at least one camera sensor 26 are not blocked by the shell body 2. Various camera sensors and flash sources can be integrated into the at least one camera housing 21. For example, the plurality of camera sensors 26 can include, but are not limited to, a time-of-flight sensor and/or an infrared sensor. The plurality of flash sources 25 can include, but are not limited to, an infrared projector and/or a red-green-blue module.

In addition to the display screen 8, the present invention can provide additional means to display media and/or to illuminate the surroundings of the shell body 2. As can be seen in FIGS. 1 through 5, the present invention may further comprise a plurality of light emitting diodes (LEDs) 31. The plurality of LEDs 31 enables the display of different media using a broader surface area on the distal shell face 6. The plurality of LEDs 31 also enables the user to emit different lights to the surroundings for ornamental purposes. So, the plurality of LEDs 31 is interspersed amongst the plurality of accessory connectors 9 to cover most of the distal shell face 6. In addition, the plurality of LEDs 31 is integrated into the distal shell face 6 to secure the plurality of LEDs 31 to the shell body 2. Furthermore, the plurality of LEDs 31 is electrically and electronically connected to the powering data connector 7 to enable the control of the plurality of LEDs 31 from the laptop's system. This way, the plurality of LEDs 31 can be used to emit light in different wavelengths and patterns for ornamental purposes around the laptop. In addition, the plurality of LEDs 31 along with the display screen 8 can be used to output different information or media. In other embodiments, different lighting devices can be implemented.

In some embodiments, the present invention can further provide a shell User Interface (UI) that enables the user to interact with the laptop's system via the lid shell 1. For example, the shell UI of the present invention may comprise at least one control button. The at least one control button can be of any suitable shape and size. The at least one control button can also be configured to emit a variety of colored light which the user can customize via the laptop's system or a software application on a remote PC device. The at least one control button can be attached to the shell body 2 using a corresponding accessory connector from the plurality of accessory connectors 9 so that the at least one control button can be positioned at the desired location on the distal shell face 6. Further, the at least one control button can be configured to interact with different software applications on the laptop's system so that the user does not have to use the laptop's integrated UI. Alternatively, the shell UI can include other control means for the user to interact with the laptop's system from the present invention including, but not limited to, dials, keys, switches, etc.

Although the invention has been explained in relation to its preferred embodiment, it is to be understood that many other possible modifications and variations can be made without departing from the spirit and scope of the invention.

What is claimed is:

1. An accessorized laptop shell case comprising:
a lid shell;
a powering data connector;
a display screen;
a plurality of accessory connectors;
the lid shell comprising a shell body, a proximal shell face, and a distal shell face;
the proximal shell face and the distal shell face being positioned opposite to each other about the lid shell;
the powering data connector being peripherally mounted to the shell body;
the plurality of accessory connectors being distributed across the distal shell face;
the plurality of accessory connectors being integrated into the shell body;
the plurality of accessory connectors being electrically and electronically connected to the powering data connector; and
the display screen being electrically and electronically engaged into at least one corresponding accessory connector from the plurality of accessory connectors.

2. The accessorized laptop shell case as claimed in claim 1 comprising:
at least one accessory compartment;
at least one accessory holder;
the at least one accessory compartment and the at least one accessory holder being peripherally mounted to the shell body; and
the at least one accessory compartment and the at least one accessory holder being mounted onto the distal shell face.

3. The accessorized laptop shell case as claimed in claim 2 comprising:
the shell body comprising a fixed peripheral edge; and
the at least one accessory compartment being centrally positioned along the fixed peripheral edge.

4. The accessorized laptop shell case as claimed in claim 2 comprising:
the at least one accessory compartment comprising at least one compartment lid, at least one compartment receptacle, and at least one snap connector;
the at least one compartment receptacle being integrated into the distal shell face; and
the at least one compartment lid being attached onto the at least one compartment receptacle by the at least one snap connector.

5. The accessorized laptop shell case as claimed in claim 1 comprising:
at least one deployable light;
the at least one deployable light being peripherally positioned to the shell body; and
the at least one deployable light being electrically and electronically engaged into at least one corresponding accessory connector from the plurality of accessory connectors.

6. The accessorized laptop shell case as claimed in claim 5 comprising:
the shell body comprising at least one free peripheral edge;
the at least one deployable light comprising at least one light housing and at least one light source;
the at least one light housing being centrally positioned along the at least one free peripheral edge;
the at least one light housing being mounted onto the distal shell face;
an elongated opening of the at least one light housing being oriented towards the at least one free peripheral edge; and
the at least one light source being slidably mounted into the at least one light housing.

7. The accessorized laptop shell case as claimed in claim 1 comprising:
a wireless communication module;
the wireless communication module being mounted within the shell body; and
the wireless communication module being electrically and electronically connected to the powering data connector.

8. The accessorized laptop shell case as claimed in claim 1 comprising:
at least one data port;
the at least one data port being peripherally positioned to the shell body; and
the at least one data port being electrically and electronically connected to the powering data connector.

9. The accessorized laptop shell case as claimed in claim 8 comprising:
the shell body comprising at least one free peripheral edge and a fixed peripheral edge;
the at least one data port being oriented towards the at least one free peripheral edge; and
the at least one data port being positioned adjacent to the at least one fixed peripheral edge.

10. The accessorized laptop shell case as claimed in claim 1 comprising:
at least one media capture device;
the at least one media capture device being peripherally positioned to the shell body; and
the at least one media capture device being electrically and electronically engaged into at least one corresponding accessory connector from the plurality of accessory connectors.

11. The accessorized laptop shell case as claimed in claim 10 comprising:
the shell body comprising at least one free peripheral edge;
the at least one media capture device comprising at least one camera housing and at least one camera assembly;
the at least one camera housing being centrally positioned along the at least one free peripheral edge;
the at least one camera housing being mounted onto the distal shell face;
an elongated opening of the at least one camera housing being oriented towards the at least one free peripheral edge; and
the at least one camera assembly being slidably mounted into the at least one camera housing.

12. The accessorized laptop shell case as claimed in claim 11 comprising:
the at least one media capturing device further comprising an elongated assembly body, at least one imager, at least one flash source, and at least one camera sensor;
the elongated assembly body being slidably mounted into the at least one camera housing;
the at least one imager, the at least one flash source, and the at least one camera sensor being integrated along the elongated assembly body; and
the at least one imager, the at least one flash source, and the at least one camera sensor being oriented towards the proximal shell face.

13. The accessorized laptop shell case as claimed in claim 12, wherein the at least one camera sensor is a time-of-flight sensor.

14. The accessorized laptop shell case as claimed in claim 12, wherein the at least one camera sensor is an infrared sensor.

15. The accessorized laptop shell case as claimed in claim 12, wherein the at least one flash source is an infrared projector.

16. The accessorized laptop shell case as claimed in claim 12, wherein the at least one flash source is a red-green-blue module.

17. The accessorized laptop shell case as claimed in claim 1, wherein the plurality of accessory connectors is a plurality of board-to-board connectors.

18. The accessorized laptop shell case as claimed in claim 1, wherein the plurality of accessory connectors is a plurality of pin connectors.

19. The accessorized laptop shell case as claimed in claim 1, wherein the plurality of accessory connectors is a plurality of magnetic connectors.

20. The accessorized laptop shell case as claimed in claim 1 comprising:
a plurality of light emitting diodes (LEDs);
the plurality of LEDs being interspersed amongst the plurality of accessory connectors;
the plurality of LEDs being integrated into the distal shell face; and
the plurality of LEDs being electrically and electronically connected to the powering data connector.
